(19) United States
(12) Patent Application Publication
(10) Pub. No.: US 2025/0183034 A1
(43) Pub. Date: Jun. 5, 2025

(54) METHOD OF SMOOTHENING PROFILE OF PHOTORESIST

(71) Applicant: TAIWAN SEMICONDUCTOR MANUFACTURING COMPANY, LTD., Hsinchu (TW)

(72) Inventors: Jia-Lin WEI, Hsinchu City (TW); Yu-Chung SU, Hsinchu City (TW); Ching-Yu CHANG, Yilang County (TW)

(73) Assignee: TAIWAN SEMICONDUCTOR MANUFACTURING COMPANY, LTD., Hsinchu (TW)

(21) Appl. No.: 18/526,121

(22) Filed: Dec. 1, 2023

(51) Int. Cl. H01L 21/027; G03F 7/11; G03F 7/16; G03F 7/32; H01L 21/308; H01L 21/311; H01L 21/3213

(52) U.S. Cl. CPC H01L 21/0274; G03F 7/11; G03F 7/168; G03F 7/325; H01L 21/3081; H01L 21/3086; H01L 21/31144; H01L 21/32139

(57) ABSTRACT

A lithography method includes the following steps. A target layer is formed over a substrate. A photoresist composition is applied over the target layer to form a photoresist layer. The photoresist layer is exposed. A hydrophobic material is formed over the photoresist layer. A reflow process is performed to the photoresist layer and the hydrophobic material. The hydrophobic material is removed. The target layer is patterned using the photoresist layer as an etch mask.

### BACKGROUND

As modern integrated circuits shrink in size, the associated features shrink in size as well. Lithography is a mechanism by which a pattern on a mask is projected onto a substrate such as a semiconductor wafer. In areas such as semiconductor photolithography, it has become necessary to create images on the semiconductor wafer which incorporate minimum feature sizes under a resolution limit or critical dimension (CD). Semiconductor photolithography typically includes the steps of applying a coating of photoresist (also referred to as resist) on a top surface (e.g., a thin film stack) of a semiconductor wafer and exposing the photoresist to a pattern. The semiconductor wafer is then transferred to a developing chamber to remove the exposed resist, which is soluble to an aqueous developer solution. As a result, a patterned layer of photoresist exists on the top surface of the wafer.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1, 2, 3, 4, 6, 7, 8 and 9 are cross-sectional views of a semiconductor device at various stages of fabrication in accordance with various aspects of the present disclosure.

FIGS. 5A and 5B are formulae of the second polymer of the hydrophobic material in accordance with some embodiments.

FIGS. 10-13 are cross-sectional views of a semiconductor device in an intermediate stage of fabrication in accordance with some embodiments of the present disclosure.

FIG. 14A is a perspective view of the semiconductor device in an intermediate stage of fabrication in accordance with some embodiments of the present disclosure.

FIGS. 14B and 14C are cross-sectional views along line a1-al and line b1-b1 of FIG. 14A, respectively, in accordance with various aspects of the present disclosure.

FIGS. 15-18 are cross-sectional views of the semiconductor device in an intermediate stage of fabrication in accordance with some embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. As used herein, “around,” “about,” “approximately,” or “substantially” may generally mean within 20 percent, or within 10 percent, or within 5 percent of a given value or range. Numerical quantities given herein are approximate, meaning that the term “around,” “about,” “approximately,” or “substantially” can be inferred if not expressly stated. One skilled in the art will realize, however, that the values or ranges recited throughout the description are merely examples, and may be reduced or varied with the down-scaling of the integrated circuits.

The advanced lithography process, method, and materials described in the current disclosure can be used in many applications, including fin-type field effect transistors (FinFETs). For example, the fins may be patterned to produce a relatively close spacing between features, for which the above disclosure is well suited. In addition, spacers used in forming fins of FinFETs can be processed according to the above disclosure.

As semiconductor devices continue to shrink, a pitch between elements is tightened. The tightened pitch with worse image log slope (ILS) causes a worse lithography performance and a worse profile of a photoresist. For a negative tone developed (NTD) resist, there is rare description about modifying a material for lithography performance and profile improvement like positive tone developed resist.

The present disclosure provides a method for smoothing a profile of a negative tone photoresist layer such that a lithography performance of the negative tone photoresist layer can be improved.

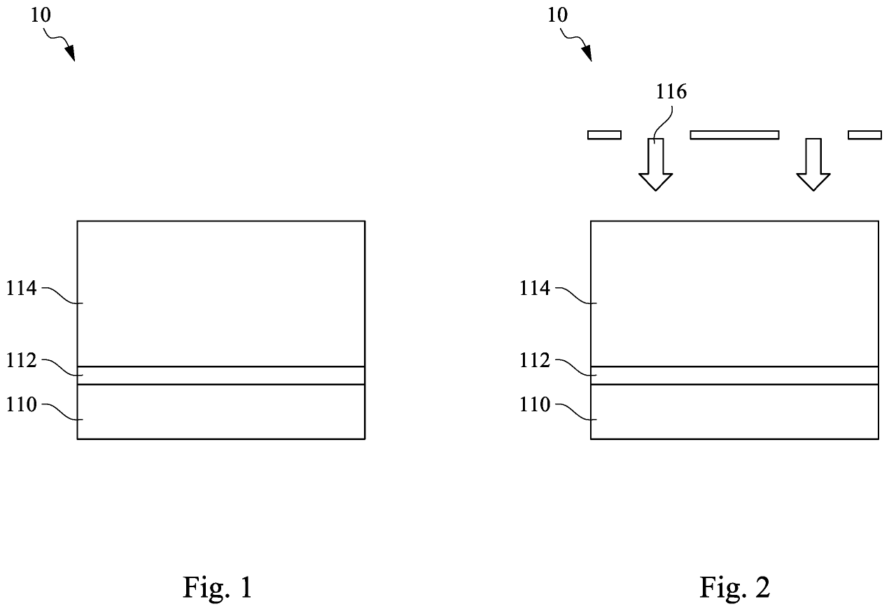

FIGS. 1, 2, 3, 4, 6, 7, 8 and 9 are cross-sectional views of a semiconductor device 10 at various stages of fabrication in accordance with various aspects of the present disclosure. Reference is made to FIG. 1. In some embodiments, a target layer 112 to be patterned is formed on a substrate 110. For example, the target layer 112 may be formed by an acceptable deposition process, such as chemical vapor deposition (CVD), physical vapor deposition (PVD), atomic layer deposition (ALD), spin coating process, or the like. The substrate 110 may include an integrated circuit (IC) chip, system on chip (SoC), or a portion thereof, and may include various passive and active microelectronic devices such as resistors, capacitors, inductors, diodes, metal-oxide semiconductor field effect transistors (MOSFET), complementary metal-oxide semiconductor (CMOS) transistors, bipolar junction transistors (BJT), laterally diffused MOS (LDMOS) transistors, high power MOS transistors, or other types of transistor.

In some embodiments, the substrate 110 is a silicon substrate doped with a p-type dopant such as boron (for example a p-type substrate). Alternatively, the substrate 110 could be another suitable semiconductor material. For example, the substrate 110 may be a silicon substrate that is doped with an n-type dopant such as phosphorous or arsenic (an n-type substrate). The substrate 110 could include other elementary semiconductors such as germanium and diamond. The substrate 110 could optionally include a compound semiconductor and/or an alloy semiconductor. Further, the substrate 110 could include an epitaxial layer (epi layer), may be strained for performance enhancement, and may include a silicon-on-insulator (SOI) structure.

In some embodiments, the target layer 112 is substantially conductive or semi-conductive. The electrical resistance may be less than about 103 ohm-meter. In some embodiments, the target layer 112 contains metal, metal alloy, or metal nitride/sulfide/selenide/oxide/silicide with the formula MXa, where M is a metal, and X is N, S, Se, O, Si, and where “a” is in a range from about 0.4 to 2.5. For example, the target layer 112 may contain Ti, Al, Co, Ru, TiN, WN2, or TaN.

In some other embodiments, the target layer 112 contains a dielectric material with a dielectric constant in a range from about 1 to about 40. In some other embodiments, the target layer 112 contains Si, metal oxide, or metal nitride, where the formula is MXb, wherein M is a metal or Si, and X is N or O, and wherein “b” is in a range from about 0.4 to 2.5. For example, the target layer 112 may contain SiO₂, silicon nitride, aluminum oxide, hafnium oxide, or lanthanum oxide.

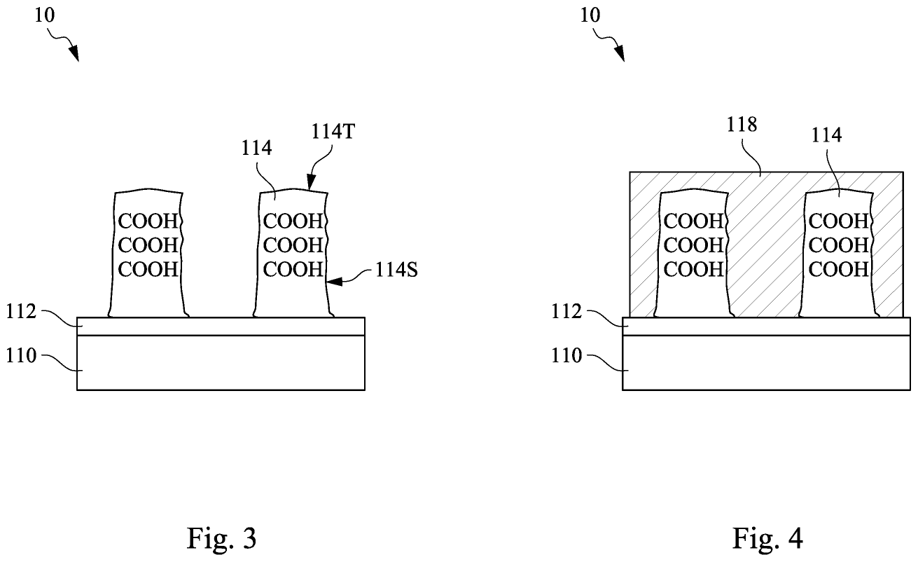

A photoresist composition is applied on the target layer 112 to form a photoresist layer 114. The photoresist composition applied on the target layer 112 to form the photoresist layer 114 may be applied by spin coating process or deposition process. In some embodiments, the photoresist composition includes a solvent, a first polymer and a photo acid generator (PAG). For example, the first polymer of the photoresist composition may include a polymer backbone and one or more acid labile groups (ALGs) bonded to the polymer backbone. The PAG may release an acid by an exposure using a radiation of light. The acid released by the PAG will cleave the ALGs in a subsequent post exposure baking (PEB) process such that the first polymer becomes more hydrophilic (see carboxyl group (—COOH) in FIG. 3). In other words, a polarity of the first polymer in an exposed region of the photoresist layer 114 changes from hydrophobic polarity to hydrophilic polarity. In some embodiments, after the photoresist layer 114 is formed, a soft bake process is performed to the photoresist layer 114 to reduce the solvent in the photoresist layer 114. For example, the solvent may be partially evaporated by the soft bake process.

Reference is made to FIG. 2. The photoresist layer 114 is exposed to an actinic radiation 116. In some embodiments, the photoresist layer 114 is exposed to the actinic radiation 116 with an illumination wavelength which is substantially less than about 250 nm. For example, the actinic radiation 116 may include at least one of the KrF, ArF, extreme ultraviolet (EUV) radiation, E-beam or the like.

In some embodiments, after exposing the photoresist layer 114 to the actinic radiation 116, a post-exposure bake (PEB) process is performed to the photoresist layer 114 to intensify the chemical amplified reaction. As discussed above, the PEB process allow the acid released by the PAG to cleave the ALGs such that the first polymer of the photoresist layer 114 has a hydrophilic polarity (or has carboxyl group (—COOH)).

The photoresist layer 114 is subsequently developed using a developer such as a solvent-based solution which is a negative tone developer (NTD), such as n-butyl acetate (nBA). An unexposed region of the photoresist layer 114 may be removed by a developer while an exposed region of the photoresist layer 114 remains. The resulting structure is shown in FIG. 3. After the photoresist layer 114 is developed, the photoresist layer 114 may have a rough profile. For example, when viewed from a cross-sectional view, the photoresist layer 114 has rough opposite sidewalls 114S and a rough top surface 114T. As discussed above, the first polymer of the photoresist layer 114 becomes more hydrophilic and has carboxyl groups (—COOH).

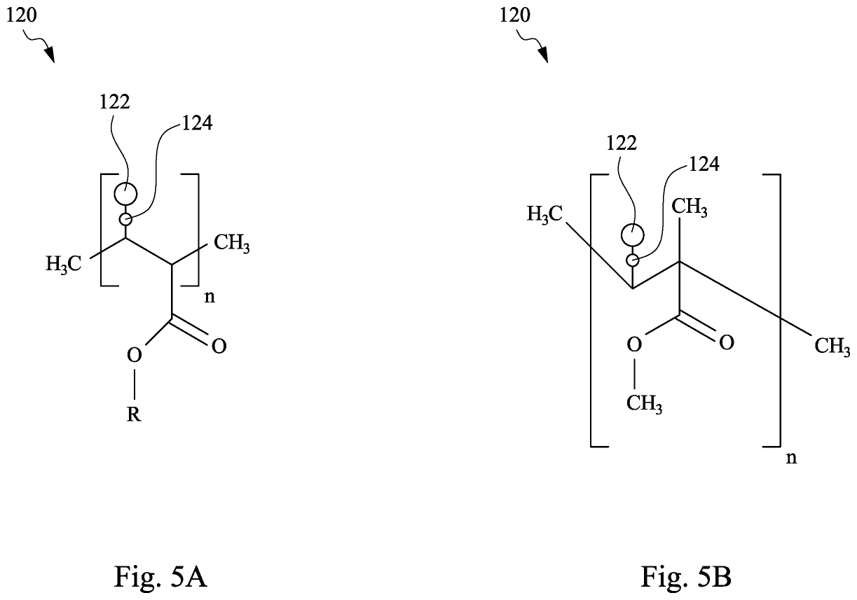

Reference is made to FIG. 4. In some embodiments, a hydrophobic material 118 is formed on the photoresist layer 114 to surround the photoresist layer 114. For example, the hydrophobic material 118 covers the sidewalls 114S and the top surface 114T of the photoresist layer 114. The hydrophobic material 118 has a composition different from a composition of the photoresist composition. For example, the hydrophobic material 118 may include a second polymer 120 (see FIG. 5A), a solvent, and a plasticizer in which the plasticizer is configured to adjust a glass transition temperature of the hydrophobic material 118. The hydrophobic material 118, which includes the second polymer, the solvent and the plasticizer, does not intermix with the photoresist layer 114. The second polymer has a high glass transition temperature and a high molecular weight such that the second polymer is rigid enough for reflowing at a low rate during a subsequent reflow process. Therefore, the hydrophobic material 118 acts as a wall with a hardness greater than a hardness of the photoresist layer 114. For example, the second polymer has a glass transition temperature greater than about 130° C., and a molecule weight greater than about 8000. If the glass transition temperature of the second polymer is less than about 130° C. or the molecule weight of the second polymer is less than about 8000, the second polymer may not be rigid enough for reflowing at a low rate during a subsequent reflow process. The solvent of the hydrophobic material 118 can be made of a developer such as a negative tone developer (NTD), for example, n-butyl acetate (nBA). In other words, the solvent is a hydrophobic solvent.

FIGS. 5A and 5B are formulae of the second polymer 120 of the hydrophobic material 118 in accordance with some embodiments. Reference is made to FIGS. 4 and 5A. In some embodiments, the second polymer 120 of the hydrophobic material 118 is an acrylate-based polymer. In other words, the second polymer 120 has a backbone of acrylate. In some embodiments, the second polymer 120 has a cyclic monomer 122 bonded to the backbone through a linker moiety 124 such that the second polymer 120 can have an increased glass transition temperature. The cyclic monomer 122 may be a 2-dimensional (2D) cyclic structure or a 3-dimensional (3D) cyclic structure. The cyclic monomer 122 may contain lactone, OH group, or only carbon atoms. For example, the cyclic monomer 122 with the 2D cyclic structure may be represented by one of formulae (1) to (3):

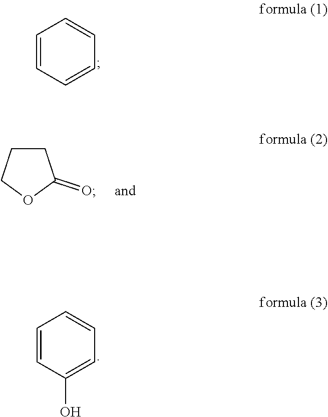 [SMILES: c1ccccc1 ; O=C1CCCO1 ; Oc1ccccc1]

For example, the cyclic monomer 122 with the 3D cyclic structure may be represented by one of formulae (4) to (6):

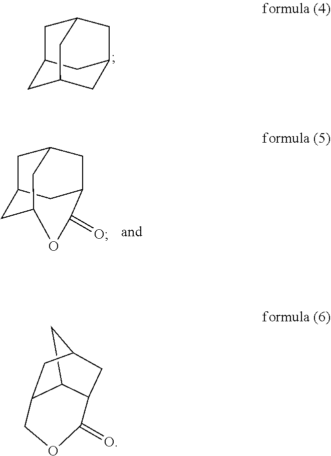 [SMILES: C1C2CC3CC1CC(C2)C3 ; O=C1OC2CC3CC(C2)CC1C3 ; O=C1OCC2CC3CC1C2C3]

In some embodiments, the linker moiety 124 includes hydrocarbons with carbon atoms of 1 to 3, COOH, the like, or a combination thereof. Reference is made to FIGS. 4 and 5B. In some embodiments, the second polymer 120 of the hydrophobic material 118 is a methyl methacrylate-based polymer. In other words, the second polymer 120 has a backbone of methyl methacrylate. In some embodiments, the second polymer 120 has the cyclic monomer 122 bonded to the backbone through the linker moiety 124, as discussed previously with regard to FIG. 5A. The description thereof is thus omitted herein.

In some embodiments, the solvent of the hydrophobic material 118 has a cLogP greater than or equal to a cLogP of the butyl acetate, which is about 1.8. That is, the solvent is more hydrophobic than the developer in some embodiments. The cLogP is a logP value of a compound, which is the logarithm of its partition coefficient between n-octanol and water log (Coctanol/Cwater), is a measure of the compound's hydrophilicity. In some embodiments, the solvent has the cLogP in a range from about 1.8 to about 10. If the cLogP of the solvent is less than about 1.8, the solvent might not be easily dissolved by the butyl acetate, which may be used to remove the hydrophobic material 118 in a subsequent process. In some embodiments, the solvent of the hydrophobic material 118 is butyl acetate, a hydrophobic solvent, the like, or a combination thereof.

Since the plasticizer is configured to adjust the glass transition temperature of the hydrophobic material 118, the plasticizer has a low molecular weight. In some embodiments, the plasticizer is a polymer having a molecular weight lower than a molecular weight of the second polymer. In some embodiments, the plasticizer is a small molecule including a rotatable moiety such as a long chain of carbon atoms, a C—O bond, a C═O bond, a C═N bond, the like, or a combination thereof at a backbone of the molecule, a side chain of the molecule, or as an end group of the molecule.

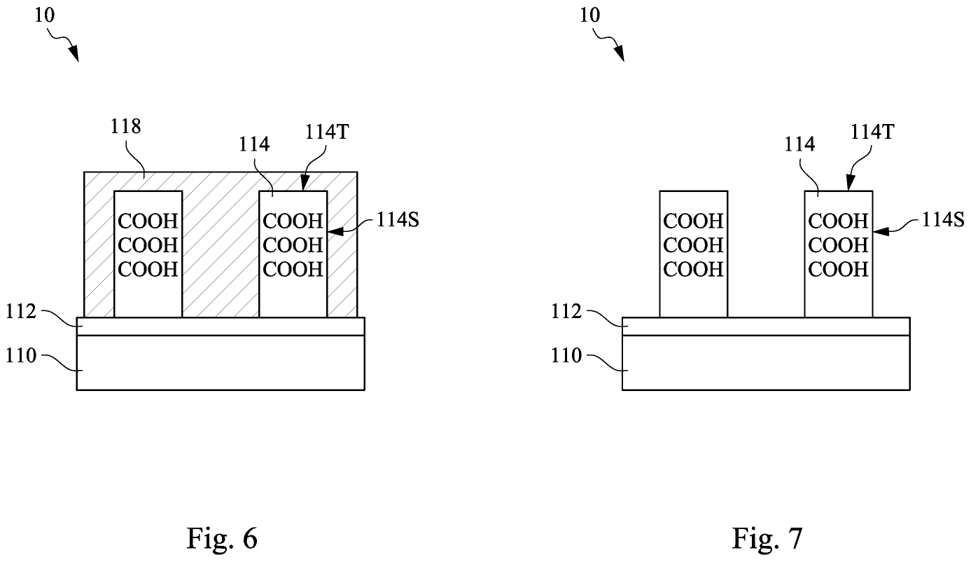

Reference is made to FIG. 6. A reflow process is performed to the photoresist layer and the hydrophobic material 118 to smooth a profile of the photoresist layer 114, for example, by heating. The glass transition temperature of the hydrophobic material 118 is higher than the glass transition temperature of the photoresist layer 114. Therefore, during the reflow process, the hydrophobic material 118 acts as a wall for the photoresist layer 114 to allow the reflow process uses a surface tension of the photoresist layer 114 to make the photoresist layer 114 have a smooth profile. In other words, from a cross-sectional view, the photoresist layer 114 may have the straight opposite sidewalls 114S and the substantially flat top surface 114T such that a lithography performance of the photoresist layer 114 can be improved.

Reference is made to FIG. 7. After performing the reflow process, the hydrophobic material 118 can be removed by using, for example, a suitable solvent, such as a developer, for example, butyl acetate or other suitable NTD developers. In some embodiments, the solvent used to remove the hydrophobic material 118 is the same as the developer used to develop the photoresist layer 114. In other words, the solvent used to remove the hydrophobic material 118 and the developer used to develop the photoresist layer 114 include the same composition. The photoresist layer 114 is thus exposed.

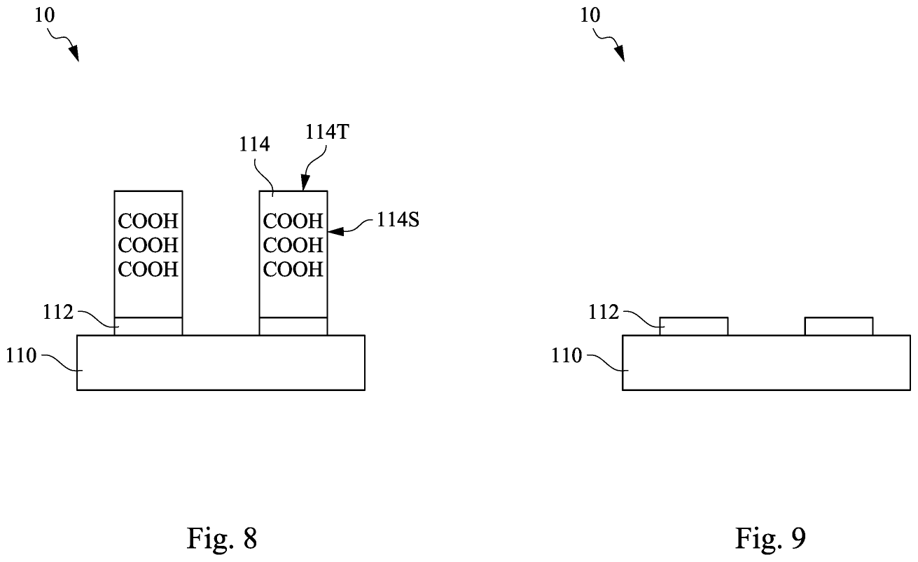

Reference is made to FIG. 8. An etch process is performed to the target layer 112 using the photoresist layer 114 as an etch mask. For example, the etch process is a dry etch process including a biased plasma etch process that uses a chlorine-based chemistry, CF₄, NF₃, SF₆, or the like. The dry etch process may be performed anisotropically. The photoresist layer 114 is removed after etching the target layer 112 by using a suitable photoresist stripper solvent or by a photoresist ashing operation. The resulting structure is shown in FIG. 9.

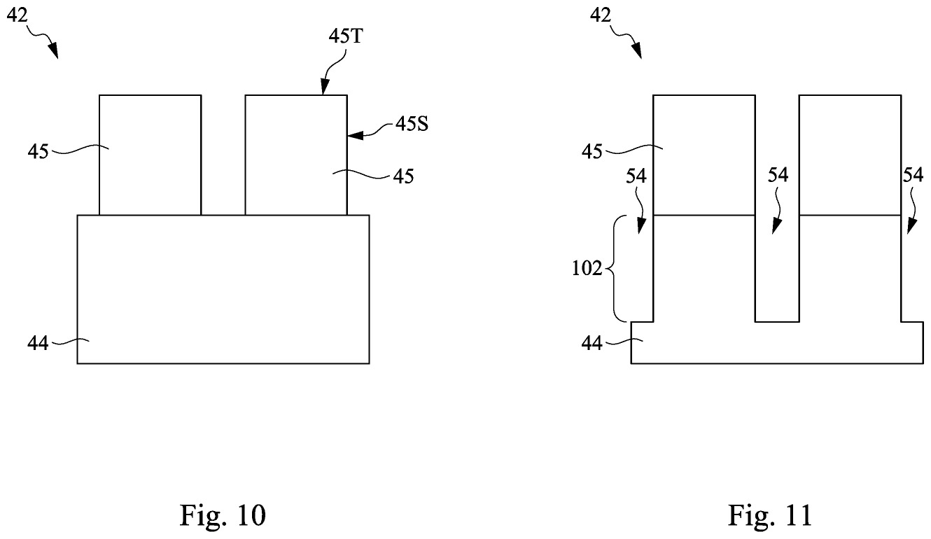

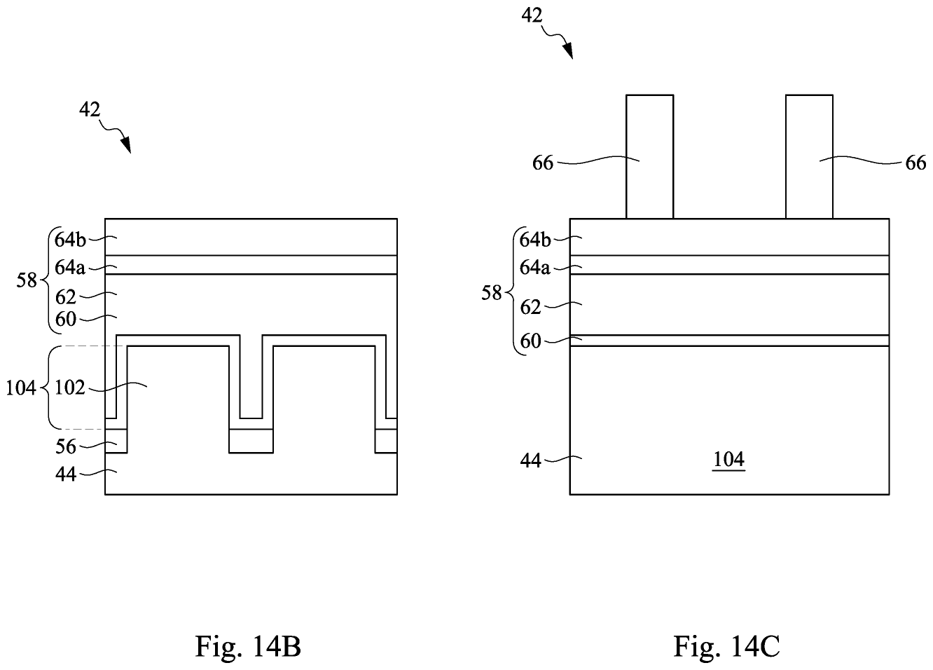

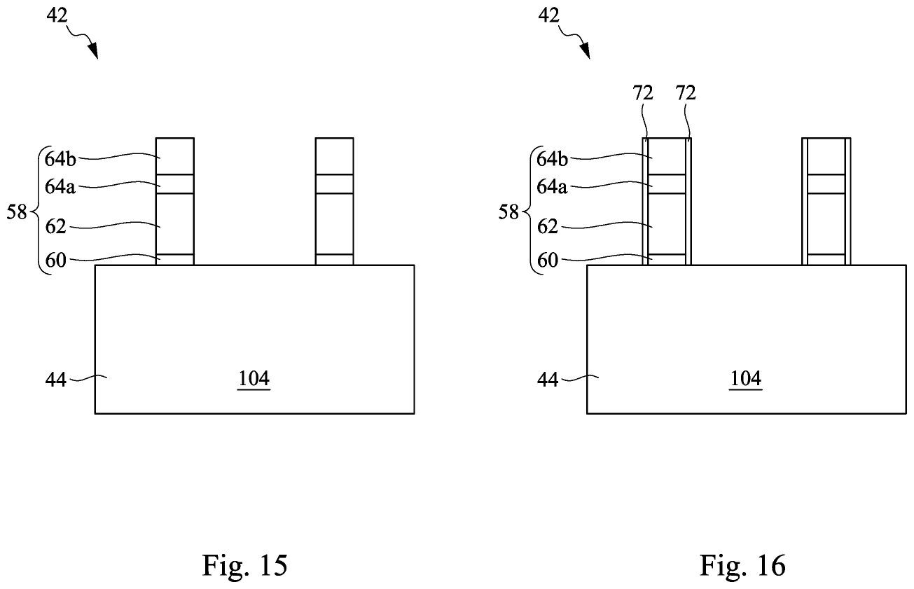

FIGS. 10-13 are cross-sectional views of a semiconductor device 42 in an intermediate stage of fabrication in accordance with some embodiments of the present disclosure. FIG. 14A is a perspective view of the semiconductor device 42 in an intermediate stage of fabrication in accordance with some embodiments of the present disclosure. FIGS. 14B and 14C are cross-sectional views along line a1-a1 and line b1-b1 of FIG. 14A, respectively, in accordance with various aspects of the present disclosure. FIGS. 15-18 are cross-sectional views of the semiconductor device 42 in an intermediate stage of fabrication in accordance with some embodiments of the present disclosure. Reference is made to FIG. 10. A photoresist layer 45 is formed on a substrate 44. The photoresist layer 45 and the substrate 44 are similar to the photoresist layer 114 and the substrate 110 in terms of composition as discussed previously with regard to FIG. 1, and thus the description thereof is omitted herein. After the photoresist layer 45 is formed, a plurality of processes including forming a hydrophobic material surrounding the photoresist layer 45, performing a reflow process to the photoresist layer 45 and the hydrophobic material, and removing the hydrophobic material may be performed to the photoresist layer 45 to make the photoresist layer 45 have straight opposite sidewalls 45S and a substantially flat top surface 45T, as discussed previously with regard to FIGS. 4-7.

Reference is made to FIG. 11. An etch process is performed to the substrate 44 using the photoresist layer 45 as an etch mask such that trenches 54 are formed in the substrate 44. The etch process may be a dry etch, a wet etch, or a combination thereof.

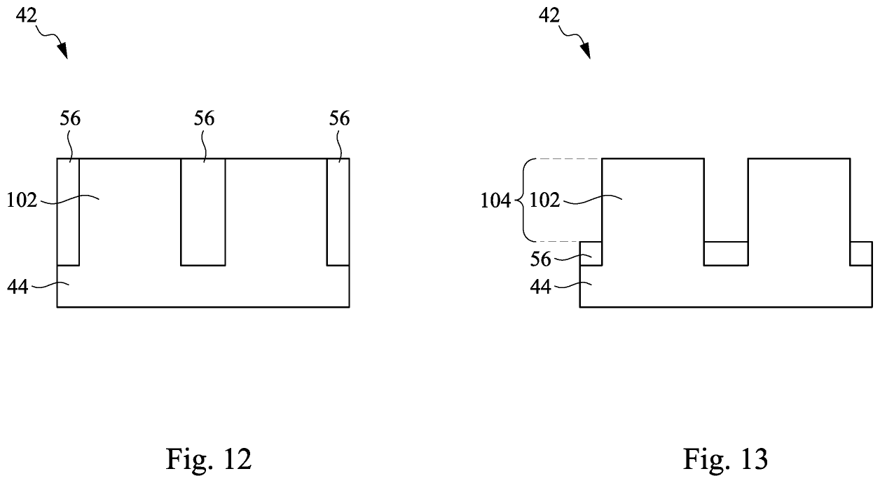

The photoresist layer 45 is removed after etching the substrate 44 by using a suitable photoresist stripper solvent or by a photoresist ashing operation. Isolation regions such as shallow trench isolation (STI) regions 56 may be formed on the substrate 44, filling into the trenches 54. The resulting structure in shown in FIG. 12.

The STI regions 56 may include a liner oxide (not shown). The liner oxide may be formed of a thermal oxide formed through a thermal oxidation of a surface layer of the substrate 44. The liner oxide may also be a deposited silicon oxide layer formed using, for example, Atomic Layer Deposition (ALD), High-Density Plasma Chemical Vapor Deposition (HDPCVD), or Chemical Vapor Deposition (CVD). The STI regions 56 may also include a dielectric material over the liner oxide, and the dielectric material may be formed using flowable chemical vapor deposition (FCVD), spin-on coating, or the like.

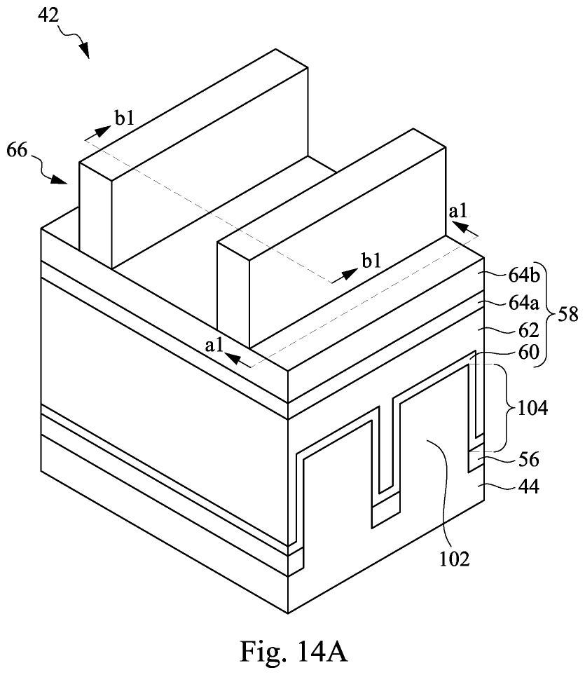

Referring to FIG. 13, the STI regions 56 are recessed, so that the top portions of semiconductor strips 102 protrude higher than top surfaces of the neighboring STI regions 56 to form protruding fins 104. The etching may be performed using a dry etching process or a wet etching process.

Referring to FIGS. 14A-14C, a dummy gate stack 58 is formed on top surfaces and sidewalls of the protruding fins 104. The dummy gate stack 58 may include a dummy gate dielectric 60 and a dummy gate electrode 62 over the dummy gate dielectric 60. The dummy gate dielectric 60 may be, for example, silicon oxide, silicon nitride, a combination thereof, or the like, and may be deposited or thermally grown according to acceptable techniques. The dummy gate electrode 62 may be deposited over the dummy gate dielectric 60 and then planarized, such as by a CMP. The dummy gate electrode 62 may be deposited by PVD, CVD, sputter deposition, or other techniques for depositing the selected material.

The dummy gate dielectric 60 may further include an interfacial layer (not shown) including silicon oxide. The dummy gate electrode 62 may be formed, for example, using polysilicon, and other materials may also be used. The dummy gate electrode 62 may be made of other materials that have a high etching selectivity from the etching of STI regions 56. The dummy gate stack 58 may also include hard mask layers 64a and 64b over the dummy gate electrode 62. The hard mask layers 64a and 64b may be formed of silicon nitride and silicon oxide, respectively. The dummy gate stack 58 may cross over a single one or a plurality of protruding fins 104 and/or STI regions 56. The dummy gate stack 58 also has a lengthwise direction perpendicular to the lengthwise directions of protruding fins 104.

A photoresist layer 66 is formed over the dummy gate stack 58. In some embodiments, a pad layer (not shown) and a hard mask layer (not shown) may be formed between the photoresist layer 66 and the dummy gate stack 58. The pad layer and the hard mask layer have an etch selectivity with respect to the photoresist layer 66. The pad layer may be a silicon oxide layer and the hard mask layer may be a silicon nitride layer, for example. The above discussion of the operation to treating the photoresist layer 114 applies to the photoresist layer 66, unless mentioned otherwise. Therefore, the photoresist layer 66 can have a smooth profile. A lithography performance of the photoresist layer 66 is thus improved.

In FIG. 15, using the photoresist layer 66 (see FIG. 14C) as a mask, the pattern of the photoresist layer 66 are extended into the dummy gate stack 58 by etching, using one or more suitable etchants. In some embodiments, the photoresist layer 66 is removed after etching the dummy gate stack 58 by using a suitable photoresist stripper solvent or by a photoresist ashing operation.

Next, as illustrated in FIG. 16, gate spacers 72 are formed on sidewalls of the dummy gate stack 58. In some embodiments of the gate spacer formation step, a spacer material layer is deposited on the substrate 44 and the dummy gate stack 58. The spacer material layer may be a conformal layer that is subsequently etched back to form gate spacers 72. The spacer material layer is made of a low-k dielectric material. The low-k dielectric material has a dielectric constant (k value) of lower than about 3.5. Suitable materials for the low-k dielectric material may include, but are not limited to, doped silicon dioxide, fluorinated silica glass (FSG), carbon-doped silicon dioxide, porous silicon dioxide, porous carbon-doped silicon dioxide, SiLK™ (an organic polymeric dielectric distributed by Dow Chemical of Michigan), Black Diamond (a product of Applied Materials of Santa Clara, Calif.), Xerogel, Aerogel, amorphous fluorinated carbon, Parylene, bis-benxocyclocutenes (BCB), polyimide, polynoroboneses, benzocyclocutene, PTFE, porous SiLK, hydrogen silsesquioxane (HSQ), methylsilsesquioxane (MSQ), and/or combinations thereof. By way of example and not limitation, the spacer material layer may be formed using processes such as, CVD process, a subatmospheric CVD (SACVD) process, a flowable CVD process, an ALD process, a physical vapor deposition (PVD) process, or other suitable process. An anisotropic etching process is then performed on the deposited spacer material layer to expose portions of the fins 104 not covered by the dummy gate stack 58 (e.g., in source/drain regions of the fins 104). Portions of the spacer material layer directly above the dummy gate stack 58 may be completely removed by this anisotropic etching process. Portions of the spacer material layer on sidewalls of the dummy gate stack 58 may remain, forming gate spacers, which are denoted as the gate spacers 72, for the sake of simplicity. In some embodiments, the gate spacers 72 may be used to offset subsequently formed doped regions, such as source/drain regions. The gate spacers 72 may further be used for designing or modifying the source/drain region profile.

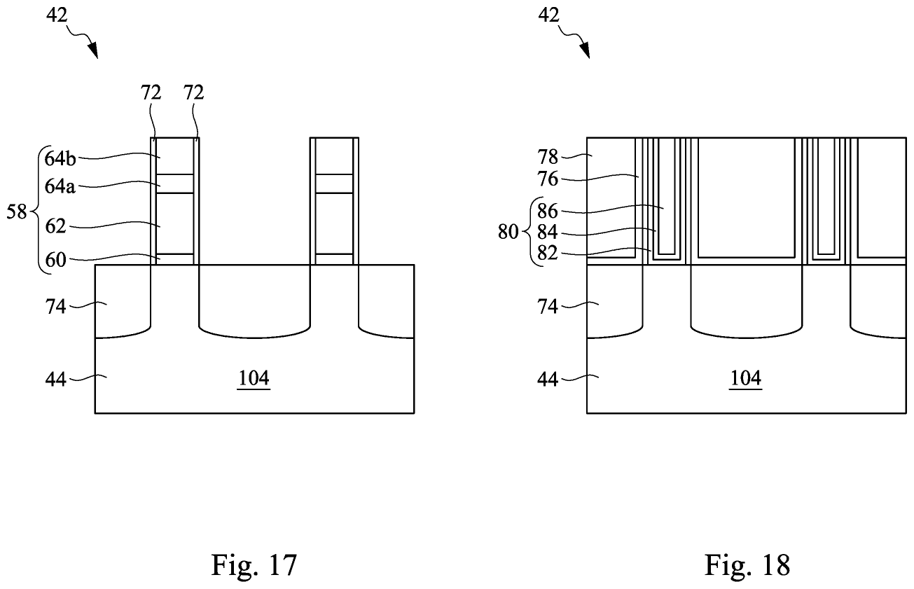

In FIG. 17, after formation of the gate spacers 72 is completed, source/drain epitaxial structures 74 are formed on source/drain regions of the protruding fins 104 that are not covered by the dummy gate stack 58 and the gate spacers 72. In some embodiments, formation of the source/drain epitaxial structures 74 includes recessing source/drain regions of the fins 104, followed by epitaxially growing semiconductor materials in the recessed source/drain regions of the fins 104. The source/drain epitaxial structures 74 are on opposite sides of the dummy gate stack 58.

The source/drain regions of the fins 104 can be recessed using suitable selective etching processing that attacks the fins 104, but hardly attacks the gate spacers 72 and the hard mask layer 64b of the dummy gate stack 58. For example, recessing the fins 104 may be performed by a dry chemical etch with a plasma source and an etchant gas. The plasma source may be inductively coupled plasma (ICR) etch, transformer coupled plasma (TCP) etch, electron cyclotron resonance (ECR) etch, reactive ion etch (RIE), or the like and the etchant gas may be fluorine, chlorine, bromine, combinations thereof, or the like, which etches the protruding fins 104 at a faster etch rate than it etches the gate spacers 72 and the hard mask layer 64b of the dummy gate stack 58. In some other embodiments, recessing the protruding fins 104 may be performed by a wet chemical etch, such as ammonium peroxide (APM), NH₄OH, tetramethylammonium hydroxide (TMAH), combinations thereof, or the like, which etches the fins 104 at a faster etch rate than it etches the gate spacers 72 and the hard mask layer 64b of the dummy gate stack 58. In some other embodiments, recessing the protruding fins 104 may be performed by a combination of a dry chemical etch and a wet chemical etch.

Once recesses are created in the source/drain regions of the fins 104, source/drain epitaxial structures 74 are formed in the source/drain recesses in the fins 104 by using one or more epitaxy or epitaxial (epi) processes that provides one or more epitaxial materials on the protruding fins 104. During the epitaxial growth process, the gate spacers 72 limit the one or more epitaxial materials to source/drain regions in the fins 104. In some embodiments, the lattice constants of the source/drain epitaxial structures 74 are different from the lattice constant of the fins 104, so that the channel region in the fins 104 and between the source/drain epitaxial structures 74 can be strained or stressed by the source/drain epitaxial structures 74 to improve carrier mobility of the semiconductor device and enhance the device performance. The epitaxy processes include CVD deposition techniques (e.g., PECVD, vapor-phase epitaxy (VPE) and/or ultra-high vacuum CVD (UHV-CVD)), molecular beam epitaxy, and/or other suitable processes. The epitaxy process may use gaseous and/or liquid precursors, which interact with the composition of the fins 104.

In some embodiments, the source/drain epitaxial structures 74 may include Ge, Si, GaAs, AlGaAs, SiGe, GaAsP, SiP, or other suitable material. The source/drain epitaxial structures 74 may be in-situ doped during the epitaxial process by introducing doping species including: p-type dopants, such as boron or BF2; n-type dopants, such as phosphorus or arsenic; and/or other suitable dopants including combinations thereof. If the source/drain epitaxial structures 74 are not in-situ doped, an implantation process (i.e., a junction implant process) is performed to dope the source/drain epitaxial structures 74. In some exemplary embodiments, the source/drain epitaxial structures 74 in an n-type transistor include SiP, while those in a p-type include GeSnB and/or SiGeSnB. In embodiments with different device types, a mask, such as a photoresist, may be formed over n-type device regions, while exposing p-type device regions, and p-type epitaxial structures may be formed on the exposed fins 104 in the p-type device regions. The mask may then be removed. Subsequently, a mask, such as a photoresist, may be formed over the p-type device region while exposing the n-type device regions, and n-type epitaxial structures may be formed on the exposed fins 104 in the n-type device region. The mask may then be removed.

Once the source/drain epitaxial structures 74 are formed, an annealing process can be performed to activate the p-type dopants or n-type dopants in the source/drain epitaxial structures 74. The annealing process may be, for example, a rapid thermal anneal (RTA), a laser anneal, a millisecond thermal annealing (MSA) process or the like.

Next, in FIG. 18, a contact etch stop layer (CESL) 76 and an interlayer dielectric (ILD) layer 78 are formed on the substrate 44 in sequence. In some examples, the CESL 76 includes a silicon nitride layer, silicon oxide layer, a silicon oxynitride layer, and/or other suitable materials having a different etch selectivity than the ILD layer 78. The CESL 76 may be formed by plasma-enhanced chemical vapor deposition (PECVD) process and/or other suitable deposition or oxidation processes. In some embodiments, the ILD layer 78 includes materials such as tetraethylorthosilicate (TEOS) oxide, un-doped silicate glass, or doped silicon oxide such as borophosphosilicate glass (BPSG), fused silica glass (FSG), phosphosilicate glass (PSG), boron doped silicon glass (BSG), and/or other suitable dielectric materials having a different etch selectivity than the CESL 76. The ILD layer 78 may be deposited by a PECVD process or other suitable deposition technique. In some embodiments, after formation of the ILD layer 78, the wafer may be subject to a high thermal budget process to anneal the ILD layer 78.

In some examples, after forming the ILD layer 78, a planarization process may be performed to remove excessive materials of the ILD layer 78 and the CESL 76. For example, a planarization process includes a chemical mechanical planarization (CMP) process which removes portions of the ILD layer 78 and the CESL 76 overlying the dummy gate stack 58. In some embodiments, the CMP process also removes hard mask layers 64a and 64b (as shown in FIG. 17) and exposes the dummy gate electrode 62.

An etching process is performed to remove the dummy gate electrode 62 and the dummy gate dielectric 60, resulting in gate trenches between corresponding gate spacers 72. The dummy gate stack 58 are removed using a selective etching process (e.g., selective dry etching, selective wet etching, or a combination thereof) that etches materials in the dummy gate stack 58 at a faster etch rate than it etches other materials (e.g., gate spacers 72 and/or the ILD layer 78).

Thereafter, replacement gate structures 80 are respectively formed in the gate trenches. The gate structures 80 may be the final gates of FinFETs. In FinFETs, the fins may be patterned by any suitable method. For example, the fins may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the fins. The final gate structures each may be a high-k/metal gate (HKMG) stack, however other compositions are possible. In some embodiments, each of the gate structures 80 forms the gate associated with the three-sides of the channel region provided by the fin 104. Stated another way, each of the gate structures 80 wraps around the fin 104 on three sides. In various embodiments, the high-k/metal gate structure 80 includes a gate dielectric layer 82 lining the gate trench, a work function metal layer 84 formed over the gate dielectric layer 82, and a fill metal 86 formed over the work function metal layer 84 and filling a remainder of gate trenches. The gate dielectric layer 82 includes an interfacial layer (e.g., silicon oxide layer) and a high-k gate dielectric layer over the interfacial layer. High-k gate dielectrics, as used and described herein, include dielectric materials having a high dielectric constant, for example, greater than that of thermal silicon oxide (˜3.9). The work function metal layer 84 and/or the fill metal 86 used within high-k/metal gate structures 80 may include a metal, metal alloy, or metal silicide. Formation of the high-k/metal gate structures 80 may include multiple deposition processes to form various gate materials, one or more liner layers, and one or more CMP processes to remove excessive gate materials.

In some embodiments, the interfacial layer of the gate dielectric layer 82 may include a dielectric material such as silicon oxide (SiO₂), HfSiO, or silicon oxynitride (SiON). The interfacial layer may be formed by chemical oxidation, thermal oxidation, atomic layer deposition (ALD), chemical vapor deposition (CVD), and/or other suitable method. The high-k dielectric layer of the gate dielectric layer 82 may include hafnium oxide (HfO2). Alternatively, the gate dielectric layer 82 may include other high-k dielectrics, such as hafnium silicon oxide (HfSiO), hafnium silicon oxynitride (HfSiON), hafnium tantalum oxide (HfTaO), hafnium titanium oxide (HfTiO), hafnium zirconium oxide (HfZrO), lanthanum oxide (LaO), zirconium oxide (ZrO), titanium oxide (TiO), tantalum oxide (Ta₂O₅), yttrium oxide (Y₂O₃), strontium titanium oxide (SrTiO3, STO), barium titanium oxide (BaTiO3, BTO), barium zirconium oxide (BaZrO), hafnium lanthanum oxide (HfLaO), lanthanum silicon oxide (LaSiO), aluminum silicon oxide (AlSiO), aluminum oxide (Al2O3), silicon nitride (Si3N4), oxynitrides (SiON), and combinations thereof.

The work function metal layer 84 may include work function metals to provide a suitable work function for the high-k/metal gate structures 80. For an n-type FinFET, the work function metal layer 84 may include one or more n-type work function metals (N-metal). The n-type work function metals may exemplarily include, but are not limited to, titanium aluminide (TiAl), titanium aluminium nitride (TiAIN), carbo-nitride tantalum (TaCN), hafnium (Hf), zirconium (Zr), titanium (Ti), tantalum (Ta), aluminum (Al), metal carbides (e.g., hafnium carbide (HfC), zirconium carbide (ZrC), titanium carbide (TiC), aluminum carbide (AIC)), aluminides, and/or other suitable materials. On the other hand, for a p-type FinFET, the work function metal layer 84 may include one or more p-type work function metals (P-metal). The p-type work function metals may exemplarily include, but are not limited to, titanium nitride (TiN), tungsten nitride (WN), tungsten (W), ruthenium (Ru), palladium (Pd), platinum (Pt), cobalt (Co), nickel (Ni), conductive metal oxides, and/or other suitable materials.

In some embodiments, the fill metal 86 may exemplarily include, but are not limited to, tungsten, aluminum, copper, nickel, cobalt, titanium, tantalum, titanium nitride, tantalum nitride, nickel silicide, cobalt silicide, TaC, TaSIN, TaCN, TiAl, TiAIN, or other suitable materials.

In some embodiments, the semiconductor device 42 includes other layers or features not specifically illustrated. In some embodiments, back end of line (BEOL) processes are performed on the semiconductor device 42. In some embodiments, the semiconductor device 42 is formed by a non-replacement metal gate process or a gate-first process.

Based on the above discussions, it can be seen that the present disclosure offers advantages over conventional methods. It is understood, however, that other embodiments may offer additional advantages, and not all advantages are necessarily disclosed herein, and that no particular advantage is required for all embodiments. One advantage is that by forming a hydrophobic material on the photoresist layer to surround the photoresist layer followed by performing a reflow process to the photoresist layer and the hydrophobic material, the hydrophobic material can act as a wall for the photoresist layer during the reflow process such that the photoresist can have a smooth profile. Another advantage is that after performing the reflow process, the hydrophobic material can be easily removed such as using a developer.

In some embodiments, a lithography method includes the following steps. A target layer is formed over a substrate. A photoresist composition is applied over the target layer to form a photoresist layer. The photoresist layer is exposed. A hydrophobic material is formed over the photoresist layer. A reflow process is performed to the photoresist layer and the hydrophobic material. The hydrophobic material is removed. The target layer is patterned using the photoresist layer as an etch mask. In some embodiments, the hydrophobic material has a glass transition temperature greater than a glass transition temperature of the photoresist layer. In some embodiments, the hydrophobic material is made of a polymer, a plasticizer and a solvent. In some embodiments, the polymer is an acrylate-based polymer or a methyl methacrylate-based polymer. In some embodiments, the polymer of the hydrophobic material comprises a backbone, a linker moiety and a cyclic monomer bonded to the backbone through the linker moiety. In some embodiments, the cyclic monomer is represented by formulae (1) to (6):

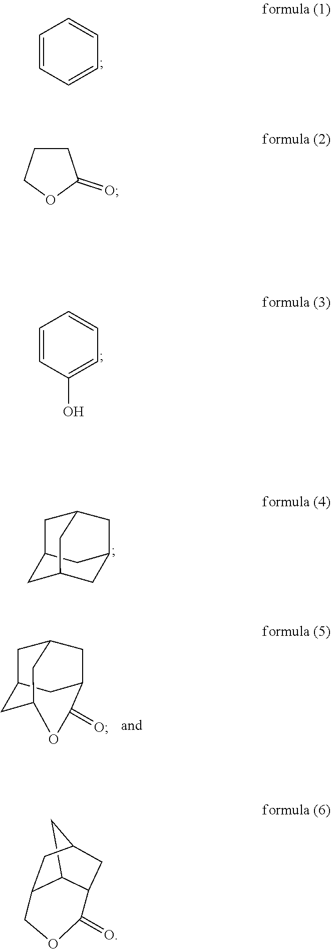 [SMILES: c1ccccc1 ; O=C1CCCO1 ; Oc1ccccc1 ; C1C2CC3CC1CC(C2)C3 ; O=C1OC2CC3CC(C2)CC1C3 ; O=C1OCC2CC3CC1C2C3]

In some embodiments, the plasticizer includes a C—O bond, a C═O bond, a C═N bond, or a combination thereof. In some embodiments, the plasticizer has a molecular weight lower than a molecular weight of the polymer. In some embodiments, the solvent is butyl acetate. In some embodiments, the method comprises after exposing the photoresist layer, developing the photoresist layer using the developer, and the solvent has a cLogP greater than or equal to about 1.8, and the solvent is more hydrophobic than the developer. In some embodiments, the polymer has a glass transition temperature greater than about 130° C. In some embodiments, the polymer has a molecular weight greater than about 8000.

In some embodiments, a lithography method includes the following steps. A target layer is formed over a substrate. A photoresist pattern is formed over the target layer. Opposite sidewalls and a top surface of the photoresist pattern are covered with a hydrophobic material, wherein the photoresist pattern is more hydrophilic than the hydrophobic material. The photoresist pattern and the hydrophobic material are heated. The hydrophobic material is removed to expose the photoresist pattern. The target layer is etched using the photoresist pattern as an etch mask. In some embodiments, removing the hydrophobic material to expose the photoresist pattern is performed using a first developer. In some embodiments, the first developer is butyl acetate. In some embodiments, wherein forming the photoresist pattern over the target layer comprises the following steps. A photoresist composition is applied on the target layer to form a photoresist layer. The photoresist layer is exposed using a radiation of light. The photoresist layer is developed using a second developer, wherein the first developer and the second developer include the same composition.

In some embodiments, a hydrophobic material comprises a solvent, a polymer dissolved in the solvent and a plasticizer dissolved in the solvent. In some embodiments, the polymer comprises a backbone, a cyclic monomer connected to the backbone and represented by formulae (1) to (6):

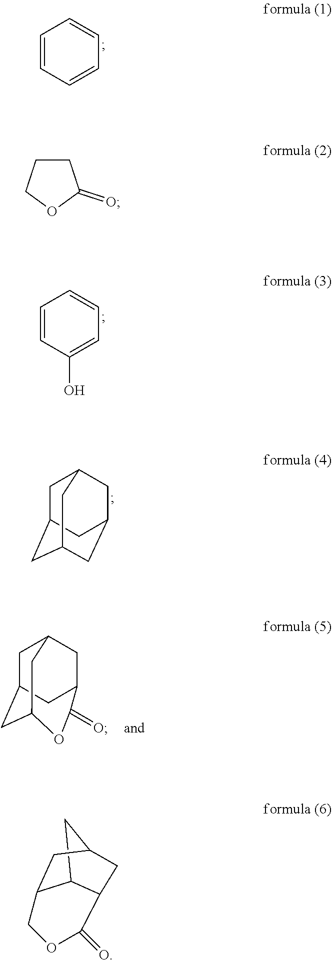 [SMILES: c1ccccc1 ; O=C1CCCO1 ; Oc1ccccc1 ; C1C2CC3CC1CC(C2)C3 ; O=C1OC2CC3CC(C2)CC1C3 ; O=C1OCC2CC3CC1C2C3]

In some embodiments, the polymer further comprises a linker moiety connected between the backbone and the cyclic monomer, the linker moiety comprising hydrocarbons with carbon atoms of 1 to 3 or COOH. In some embodiments, the polymer has a glass transition temperature greater than about 130° C. In some embodiments, the polymer is acrylate-based polymer or a methyl methacrylate-based polymer.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A lithography method, comprising:
forming a target layer over a substrate;
applying a photoresist composition over the target layer to form a photoresist layer;
exposing the photoresist layer;
forming a hydrophobic material over the photoresist layer;
performing a reflow process to the photoresist layer and the hydrophobic material;
removing the hydrophobic material; and
patterning the target layer using the photoresist layer as an etch mask.

2. The method of claim 1, wherein the hydrophobic material has a glass transition temperature greater than a glass transition temperature of the photoresist layer.

3. The method of claim 1, wherein the hydrophobic material is made of a polymer, a plasticizer and a solvent.

4. The method of claim 3, wherein the polymer is an acrylate-based polymer or a methyl methacrylate-based polymer.

5. The method of claim 3, wherein the polymer of the hydrophobic material comprises:
a backbone;
a linker moiety; and
a cyclic monomer bonded to the backbone through the linker moiety.

6. The method of claim 5, wherein the cyclic monomer is represented by formulae (1) to (6):

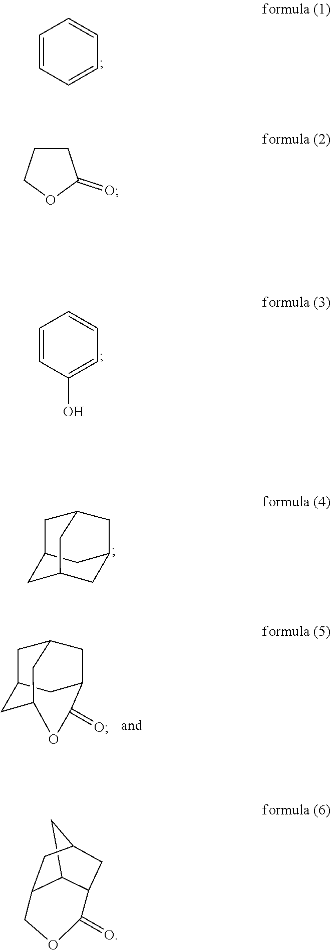 [SMILES: c1ccccc1 ; O=C1CCCO1 ; Oc1ccccc1 ; C1C2CC3CC1CC(C2)C3 ; O=C1OC2CC3CC(C2)CC1C3 ; O=C1OCC2CC3CC1C2C3]

7. The method of claim 4, wherein the plasticizer includes a C—O bond, a C═O bond, a C═N bond, or a combination thereof.

8. The method of claim 4, wherein the plasticizer has a molecular weight lower than a molecular weight of the polymer.

9. The method of claim 4, wherein the solvent is butyl acetate.

10. The method of claim 4, further comprising:
after exposing the photoresist layer, developing the photoresist layer using a developer, and wherein the solvent has a cLogP greater than or equal to about 1.8, and the solvent is more hydrophobic than the developer.

11. The method of claim 4, wherein the polymer has a glass transition temperature greater than about 130° C.

12. The method of claim 4, wherein the polymer has a molecular weight greater than about 8000.

13. A lithography method, comprising:
forming a target layer over a substrate;
forming a photoresist pattern over the target layer;
covering opposite sidewalls and a top surface of the photoresist pattern with a hydrophobic material, wherein the photoresist pattern is more hydrophilic than the hydrophobic material;
heating the photoresist pattern and the hydrophobic material;
removing the hydrophobic material to expose the photoresist pattern; and
etching the target layer using the photoresist pattern as an etch mask.

14. The method of claim 13, wherein removing the hydrophobic material to expose the photoresist pattern is performed using a first developer.

15. The method of claim 14, wherein the first developer is butyl acetate.

16. The method of claim 14, wherein forming the photoresist pattern over the target layer comprises:
applying a photoresist composition on the target layer to form a photoresist layer;
exposing the photoresist layer using a radiation of light; and
developing the photoresist layer using a second developer, wherein the first developer and the second developer include the same composition.

17. A hydrophobic material, comprising:
a solvent;
a polymer dissolved in the solvent, wherein the polymer comprises:
a backbone;
a cyclic monomer connected to the backbone and represented by formulae (1) to (6): 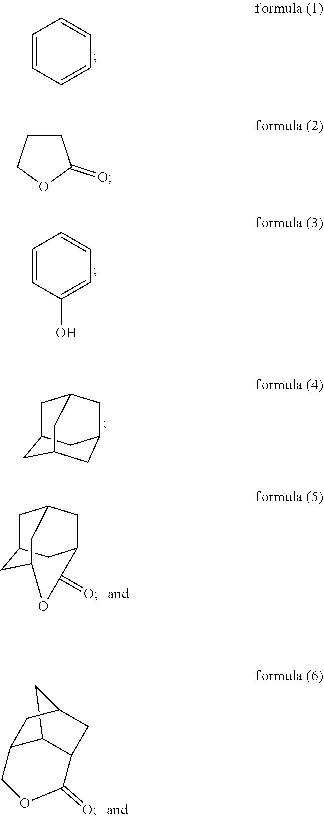 [SMILES: c1ccccc1 ; O=C1CCCO1 ; Oc1ccccc1 ; C1C2CC3CC1CC(C2)C3 ; O=C1OC2CC3CC(C2)CC1C3 ; O=C1OCC2CC3CC1C2C3]
a plasticizer dissolved in the solvent.

18. The hydrophobic material of claim 17, wherein the polymer further comprises:
a linker moiety connected between the backbone and the cyclic monomer, the linker moiety comprising hydrocarbons with carbon atoms of 1 to 3 or COOH.

19. The hydrophobic material of claim 17, wherein the polymer has a glass transition temperature greater than about 130° C.

20. The hydrophobic material of claim 17, wherein the polymer is acrylate-based polymer or a methyl methacrylate-based polymer.
